(19) United States
(12) Patent Application Publication
(10) Pub. No.: US 2024/0037296 A1
(43) Pub. Date: Feb. 1, 2024

(54) COMPARISON OF DIGITAL REPRESENTATIONS OF DRIVING SITUATIONS OF A VEHICLE

(71) Applicant: Robert Bosch Gmbh, Stuttgart (DE)

(72) Inventor: Patrick Weber, Rutesheim (DE)

(21) Appl. No.: 18/256,406

(22) PCT Filed: Dec. 2, 2021
(86) PCT No.: PCT/EP2021/084000

§ 371 Date: Jun. 7, 2023

(30) Foreign Application Priority Data
Dec. 9, 2020 (DE) 10 2020 215 535.6

(51) Int. Cl. G06F 30/20

(52) U.S. Cl. CPC G06F 30/20

(57) ABSTRACT

A method for comparing two digital representations of driving situations of a vehicle. The digital representations include occupancy information about an occupancy of the environment of the vehicle by traffic-relevant objects. The method includes: subdividing a region of the environment of the vehicle into a grid of subregions; ascertaining, based on the occupancy information in the first digital representation, the occupancies of the subregions by traffic-relevant objects, and combining them to form a fingerprint of the first driving situation; ascertaining, based on the occupancy information in the second digital representation, the occupancies of the subregions by traffic-relevant objects, and combining them to form a fingerprint of the second driving situation; ascertaining a similarity measure between the first fingerprint and the second fingerprint according to a predefined dimensional rule; determining that the two driving situations are identical or at least similar if the similarity measure satisfies the similarity measure.

### FIELD

The present invention relates to the comparison of digital representations of driving situations of a vehicle, which, for instance, is able to be used to validate the simulations of drives with the aid of recordings of drives carried out in reality.

### BACKGROUND INFORMATION

To obtain an operating permit for road travel for a vehicle, proof must be provided that this vehicle is safe in traffic. For that reason, all components and subassemblies that can have an effect on traffic safety are checked according to official regulations.

In addition, conclusive proof of the operational safety in all circumstances has to be provided for systems that allow a vehicle to be guided in traffic in an at least semi-automated manner. Such proof is very complex. Starting with the SAE automatization level 3, it is by all means possible that only 20% of the total expense invested in the implementation of a new functionality is taken up by the actual development whereas the remaining 80% is required to verify safety.

German Patent Application No. DE 10 2018 209 108 A1 describes a device which uses neural networks to predict the probability of an undesired event in a technical system.

To examine the failure of at least partly automated vehicles as the result of non-specific electrical or mechanical faults within the “Safety of the Intended Function” (SOTIF) framework, drives are simulated using these vehicles. In this context, proof (validation) is required that the simulations are sufficiently close to reality.

### SUMMARY

Within the scope of the present invention, a method is provided for comparing two digital representations of driving situations of a vehicle. These digital representations of driving situations may be available in various forms. As a minimum, however, each representation includes occupancy information relating to an occupancy of the environment of the vehicle by traffic-relevant objects.

Examples of such traffic-relevant objects are road markings, traffic lane demarcations, other road users, traffic signs as well as obstacles. The occupancy information may relate to all objects present in the environment of the vehicle or also to only certain types of objects. For instance, the occupancy information pertaining to road markings may be monitored separately from occupancy information pertaining to other road users.

Within the framework of the present method, a region of the environment of the vehicle is subdivided into a grid of subregions. This region need not necessarily extend around the entire vehicle. For example, if a comparison of traffic situations with regard to a special driving task is intended, then a region which characterizes the driving situation with regard to this driving task will suffice. If an assessment is to be made as to how well a vehicle driving in an at least partially automated manner remains within a lane, for instance, then a region of the road in front in the driving direction and including at least one traffic lane demarcation or some other indicator of the traffic lane that the vehicle is currently using will be sufficient.

Based on the occupancy information in the first digital representation, the occupancies of the subregions by traffic-relevant objects are ascertained and combined to form a fingerprint of the first driving situation. In the same way, the occupancies of the subregions by traffic-relevant objects are also ascertained based on the occupancy information in the second digital representation and combined to form a fingerprint of the second driving situation. According to a predefined measure specification, a similarity measure is ascertained between the first fingerprint and the second fingerprint. If a similarity measure satisfies a predefined criterion, it is determined that the two driving situations are identical or at least similar.

For instance, the similarity measure may particularly be any difference measure and/or distance measure that assigns a scalar or vectorial difference or distance to two fingerprints. In addition, this difference measure and/or the distance measure may also be coupled with the respective specific application case. For example, if it is to be assessed in the driving situation how well an automated system identifies or stays within the traffic lane, elements of a fingerprint characterizing the traffic lane, for example, are able to be weighted with elements of a weighting matrix ascertained based on a real traffic lane and/or a setpoint traffic lane.

It was recognized, in particular, that this allows for a very fast comparison of a specified first driving situation against a multitude of other driving situations from a given supply in order to recognize the first driving situation in the supply. For example, this may be used to call up supplementary information stored in the mentioned supply in association with the driving situation for the respective driving situation.

For instance, a stored supply of driving situations may include recordings of test drives that were performed by the automated system or also by a human test driver. If a driving situation is recognized in such a supply, then a reaction that has contributed to the successful handling of the driving situation in such a driving situation during the earlier test drive is able to be called up. The same reaction may then be used to also manage the current situation in a similar manner. An exemplary application in this context is a driver assistance system in a vehicle that is to be controlled by a human driver. For example, if a driving situation is detected during the operation of such a vehicle in which a loss of control appears imminent and a braking operation is meaningful, then this suggestion is able to be signaled to the driver. As an alternative or also in combination therewith, pressure may already be built up in the brake system in advance so that the maximum brake force is available if the driver actually initiates a braking operation.

According to an example embodiment of the present invention, in connection with an evaluation of the occupancy information, in particular, the subdivision of the region of the environment into the grid of subregions ensures that this information is both abstracted and compressed in the fingerprint. This is particularly advantageous for reducing to a common denominator the digital representations that were acquired in completely different ways and to thereby make these digital representations comparable. For example, the first representation may originate from camera images and the second representation from lidar data. In the same way, the first representation may have been produced by a simulation and the second representation by a measurement. In addition, the problem caused by the basically limited reproducibility of a sensor-acquired driving situation, which makes its recognition more difficult, is remedied. For example, even two camera images, produced in direct succession, of one and the same driving situation from the same perspective are by no means identical at the level of the recorded pixel values. However, there is no change in the objects that are present and their locations, and the subdivision into the grid of subregions thus buffers also any such fluctuations to a certain extent.

In one especially advantageous embodiment of the present invention, it is binarily detected respectively in one bit whether a subregion is occupied by at least one traffic-relevant object. This statement may refer to all possible types of traffic-relevant objects or also to only a specific type of object. Machine-based comparisons of bits and/or bit sequences may be carried out in an especially efficient manner. In this way, even the search for a specific driving situation in a very large supply of driving situations, for example, is able to be performed quickly.

For instance, in an especially advantageous embodiment of the present invention, the first digital representation is ascertained from at least one simulation of a driving situation, and the second digital representation is ascertained from at least one recording of measured data recorded with the aid of at least one sensor while a vehicle is driven. The measured data, for example, may be available in the form of unsorted time characteristics at a volume amounting to 10,000 driving hours. Moreover, no transitions between consecutive driving situations are annotated therein. With the aid of binarily encoded fingerprints, even a supply of representations of this magnitude can be searched rapidly.

According to an example embodiment of the present invention, in an especially advantageous manner, the bits acquired for all subregions are combined in a binary number as a fingerprint. Two such binary numbers, for instance, can be checked for an exact agreement by a single machine instruction. Thus, the region of the environment is also advantageously subdivided into a number of subregions that is a power of two. The power of two then advantageously corresponds to the width of a register on the hardware platform used for the comparison, that is, approximately 64 bits on a 64-bit system.

According to an example embodiment of the present invention, in an especially advantageous manner, the significance of a bit in the binary number is lower or larger the greater the importance of an object in the corresponding subregion for the behavior strategy of the vehicle in the driving situation. This makes it easier to search not only for an exact agreement of binary numbers, for example, but to allow deviations from the binary numbers within the scope of a predefined tolerance margin. If the most important features of the driving situation are identical, then this is also the case for the least significant or the most significant bits of the binary numbers.

Thus, for example, the similarity measure may be a function of the length of a bit sequence that is identical in both fingerprints. This length is able to be determined in a particularly efficient manner and then provides a direct statement as to how large the magnitude of the deviation of the two binary numbers may still be in terms of their absolute amount.

For example, if it is to be examined how well a vehicle operating in an at least partially automated manner stays within its lane, the comparison may be focused on monitoring a traffic lane demarcation in the region in front of the vehicle. If this traffic lane demarcation is located in its expected position, meaning no straying from the lane has occurred, then it has only a low relevance for the behavior strategy because the current behavior is satisfactory in the sense of the driving task and does not require any changes. The greater the distance of the traffic lane demarcation from the expected position, the farther the vehicle is located outside its setpoint lane and the more urgent a counter-steering movement. In this context, for example, it is additionally possible to consider the perspective of the monitoring. For instance, if the traffic lane demarcation has a lateral offset by a certain amount at the horizon in the far distance, then this corresponds to a considerably lower angular deviation of the vehicle course than if the traffic lane demarcation directly in front of the vehicle were to have a lateral offset by the same amount.

In a further advantageous embodiment of the present invention, the similarity measure is a function of a Hamming distance between the two fingerprints. The Hamming distance measures the number of bits by which the two fingerprints differ from one another. This is advantageous in particular if all subregions of the area of the environment of the vehicle are essentially of equal importance to the behavior strategy of the vehicle.

In a further, particularly advantageous embodiment of the present invention, the occupancies acquired for all subregions are combined in a matrix in each case, and the fingerprint is formed therefrom. In this way, for instance, the two-dimensional structure of a spatial region examined overall is retained in the fingerprint as well. A possible preprocessing of the matrix to form the matrix may consequently utilize supplementary knowledge about this two-dimensional structure.

For instance, at least the matrix generated from one of the representations may be converted into a fingerprint with the aid of filtering using at least one filter core. Through the selection of a suitable filter core, the similarity measure is able to be selectively tailored to a certain aspect of the driving situation that is of importance in the comparison. For instance, this makes it possible for the similarity measure to specifically measure the extent to which the lanes used by the vehicle are identical in the two examined driving situations.

For this purpose, for example, the similarity measure may include an average value or median of the elements in an elementwise product of both fingerprints.

The comparison of two digital representations of driving situations, for instance, may especially be utilized to validate a simulation of a drive of a vehicle. In this context, validating in particular means “anchoring” the simulation in reality. If known reference situations for a sufficient number of simulated driving situations can be found whose subsequent development is the same as that of the respective simulated situation, then it is highly likely that the simulation reproduces the reality with sufficient accuracy.

The present invention thus also provides a method for validating the simulation of a drive of a vehicle.

According to an example embodiment of the present invention, the method begins in that at least one simulated driving situation of the simulated drive is converted into a digital representation. In addition, time characteristics of reference drives are used to ascertain digital representations of a multitude of reference driving situations within the reference drives.

The digital representation of the simulated driving situation is compared according to the above-described method against the digital representations of the reference driving situations. From the results of these comparisons, at least one reference driving situation within a reference drive is ascertained that is identical or at least similar to the simulated driving situation. The similarity measure used in the search will specify what is to be considered identical or at least similar.

According to an example embodiment of the present invention, a characteristic of the simulated drive following the simulated driving situation is compared with a characteristic of the associated reference drive following the ascertained reference drive. This comparison, for instance, may relate to the entire characteristics in each case. However, the comparison may also evaluate whether both characteristics ultimately provide an identical or similar result, for example. For instance, it is less important whether a lane change is carried out rapidly and at a small radius of curvature or slowly and at a larger radius of curvature. It is simply important that the lane was ultimately changed correctly.

If the following characteristic of the simulated drive is in line with the following characteristic of the reference drive according to a predefined criterion, it is determined that the simulation of the drive is valid at least for the examined driving situation.

In this context, it is unimportant that the following characteristic of the simulated drive and/or the following characteristic of the reference drive is/are objectively correct in the individual situation. Instead, especially the occurrence of errors of the same type both in the simulation and in the reference drive may be a strong indicator that the simulation reproduces the reality with sufficient accuracy.

One pertinent example is a motor vehicle driven in an at least semi-automated manner which spontaneously turns onto an expressway exit. Certain features of such exits such as an in particular new road condition may cause a behavior planner of the vehicle to assume that the exit rather than the currently traveled right traffic lane is the continuing lane. If this error occurs both in the simulation and in identical or similar reference situations during one or more reference drive(s), then it is highly likely that the simulation covers the mechanism of action that leads to the occurrence of the error. The simulation may ultimately be used to discover the causes of the error so that these causes may subsequently be remedied.

If a simulation model is available that was validated in the described manner, it can be used to generate a large number of variations of the driving situation in an automated manner, for instance. Based on the respective subsequent development of these variations in the simulation, inferences regarding the cause of the error may then be drawn. Preferably, the pattern might then emerge that the spontaneous departure from the expressway cumulatively occurs if the road cover of the highway is new, it is raining, or the temperature is below 15° C., for instance.

In one particularly advantageous embodiment of the present invention, brake risk parameters and/or required steering potentials for mitigating the risk achieved in the following characteristics of the simulated drive on the one hand and the reference drive on the other hand are used for the comparison of these characteristics. These are established parameters for the results that are ultimately achieved by driving maneuvers starting from a driving situation.

The above-described methods, for example, may be computer-implemented and thus be embodied in a software. The present invention therefore also relates to a computer program having machine-readable instructions that when executed on one or more computer(s), induce the computer(s) to execute one of the described methods. In this sense, control units for vehicles and embedded systems for technical devices that are likewise able to execute machine-readable instructions can also be considered computers.

In the same way, the present invention also relates to a machine-readable data carrier and/or a download product having the computer program. A download product is a digital product which is transmittable via a data network, i.e., downloadable by a user of the data network, which may be offered in an online store for an immediate download, for example.

In addition, a computer may be equipped with the computer program, the machine-readable data carrier, or the download product.

In the following text, further measures that improve the present invention will be shown in greater detail together with the description of the preferred exemplary embodiment of the present invention with the aid of figures.

### BRIEF DESCRIPTION OF THE DRAWINGS

FIG. 1 an exemplary embodiment of method 100 for comparing two digital representations of driving situations of a vehicle;

FIG. 2 an exemplary embodiment of method 200 for validating a simulation of a drive of a vehicle;

FIG. 3 an exemplary subdivision of a region of the environment of a vehicle into subregions;

FIG. 4 an exemplary ascertainment of the similarity of two driving situations with the aid of filtering using a filter core 6 during the creation of fingerprint 1b.

### DETAILED DESCRIPTION OF EXAMPLE EMBODIMENTS

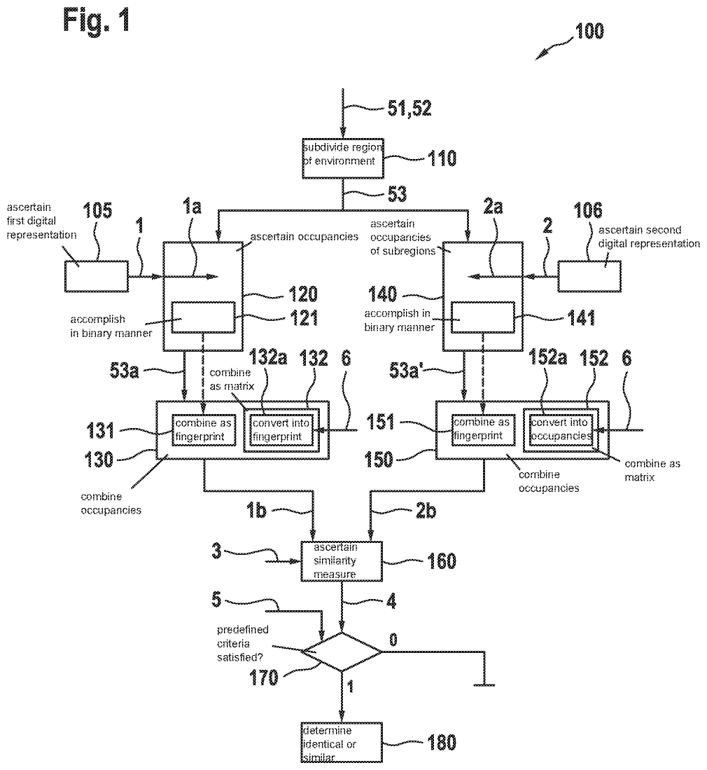

FIG. 1 is a schematic flow diagram of an exemplary embodiment of method 100 for comparing two digital representations 1, 2 of driving situations of a vehicle 50. In step 105, a first digital representation 1 is ascertained from at least one simulation of a driving situation. In step 106, a second digital representation 2 is ascertained from at least one recording of measured data recorded with the aid of at least one sensor during a drive of a vehicle 50. Both digital representations 1, 2 include occupancy information 1a, 2a relating to an occupancy of environment 51 of vehicle 50 by traffic-relevant objects. In step 110, a region 52 of environment 51 is subdivided into a grid of subregions 53.

In step 120, occupancies 53a by traffic-relevant objects of subregions 53 are ascertained based on occupancy information 1a. According to block 121, this may particularly be accomplished in a binary manner in the form of bits, each bit indicating whether or not corresponding subregion 53 is occupied by an object.

In step 130, occupancies 53a are combined to form a fingerprint 1b of the first driving situation. According to block 131, if occupancies 53a involve bits, then they are able to be combined in a binary number as a fingerprint 1b, for example. In general, occupancies 53a according to block 132 may also be combined in the form of a matrix M and fingerprint 1b be formed on that basis. According to block 132a, for example, matrix M is particularly able to be converted into fingerprint 1b with the aid of filtering using at least one filter core 6.

In step 140, as in step 120, occupancies 53a′ of subregions 53 by traffic-relevant objects are ascertained based on occupancy information 2a. According to block 141, this may especially be accomplished in a binary manner in the form of bits, each bit indicating whether or not corresponding subregion 53 is occupied by an object.

In step 150, as in step 130, occupancies 53a′ are combined into a fingerprint 2b of the first driving situation. If occupancies 53a′ are bits, they are able to be combined in a binary number as fingerprint 1b, for instance according to block 151. In general, occupancies 53a according to block 152 may also be combined in the form of a matrix M in order to form fingerprint 2b therefrom. According to block 152a, for instance, matrix M can particularly be converted into fingerprint 2b with the aid of filtering using at least one filter core 6.

In step 160, a similarity measure 4 between first fingerprint 1b and second fingerprint 2b is ascertained according to a predefined measure specification 3. In step 170, it is checked whether this similarity measure satisfies a predefined criterion 5. If this is the case (truth value 1), it is determined in step 180 that the two driving situations characterized by digital representations 1 and 2 are identical or at least similar.

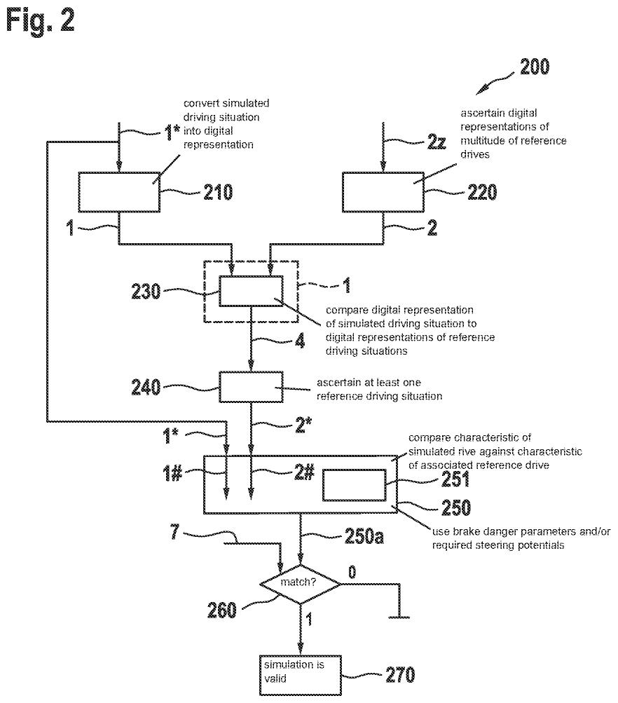

FIG. 2 is a schematic flow diagram of an exemplary embodiment of method 200 for validating a simulation of a drive of vehicle 50.

In step 210, at least one simulated driving situation 1* of the simulated drive is converted into a digital representation 1. In step 220, time characteristics 2z of reference drives are used to ascertain digital representations 2 of a multitude of reference driving situations within the reference drives. In step 230, digital representation 1 of the simulated driving situation is compared against digital representations 2 of the reference driving situations according to the above-described method 100.

In step 240, at least one reference driving situation 2* is ascertained within a reference drive based on similarities 4 ascertained from these comparisons 230. For example, this may particularly be a reference driving situation 2* for which similarity 4 is at a maximum or lies above a threshold value of a similarity measure.

In step 250, a characteristic 1# of the simulated drive following simulated driving situation 1* is compared against a characteristic 2# of the associated reference drive following ascertained reference driving situation 2*. According to block 251, for example, in particular brake danger parameters and/or required steering potentials achieved to mitigate the risk in the following characteristic 1#, 2# of the simulated drive on the one hand and the reference drive on the other hand may be used.

In step 260, result 250a of this comparison 250 is checked based on a predefined criterion 7 to determine whether subsequent characteristic 1# of the simulated drive matches following characteristic 2# of the reference drive. If this is the case (truth value 1), it is determined in step 270 that the simulation of the drive is valid at least for the examined driving situation 1*.

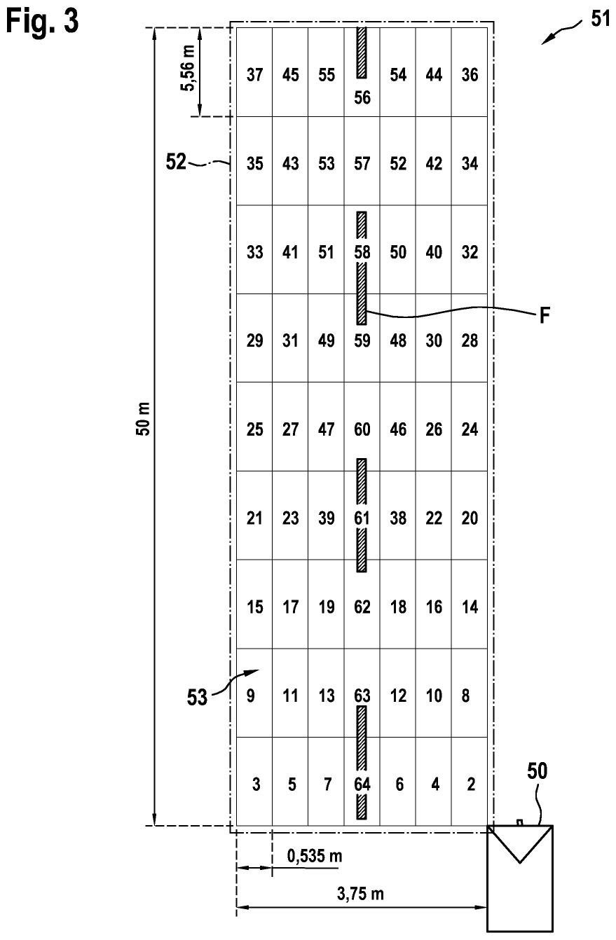

By way of example, FIG. 3 shows the manner in which a region 52 from environment 51 of vehicle 50 is able to be selected and subdivided into subregions 53. In this example, region 52 is located to the left, next to and in front of vehicle 50 in the driving direction. Region 52 is 50 m long and 3.75 m wide. It includes traffic lane demarcation F.

Region 52 is subdivided into 63 subregions 53. These subregions 53 include bit indices between 2 and 64, which indicate the extent to which the appearance of a portion of traffic lane demarcation F in the respective subregion is important for the behavior strategy of vehicle 50. The higher the bit index, the lower the importance. Thus, if traffic lane demarcation F remains where it should nominally be, it is of lesser importance. In contrast, if traffic lane demarcation F moves to an edge of region 52, then this is more important, i.e., the more so the closer this happens to vehicle 50 and the greater the angular deviation of the course of vehicle 50. The bit having the bit index 1 is reserved for indicating an error in the acquisition.

Thus, digital representation 1, 2 of the driving situation is able to be compressed in a single 64-bit number as fingerprint 1b, 2b.

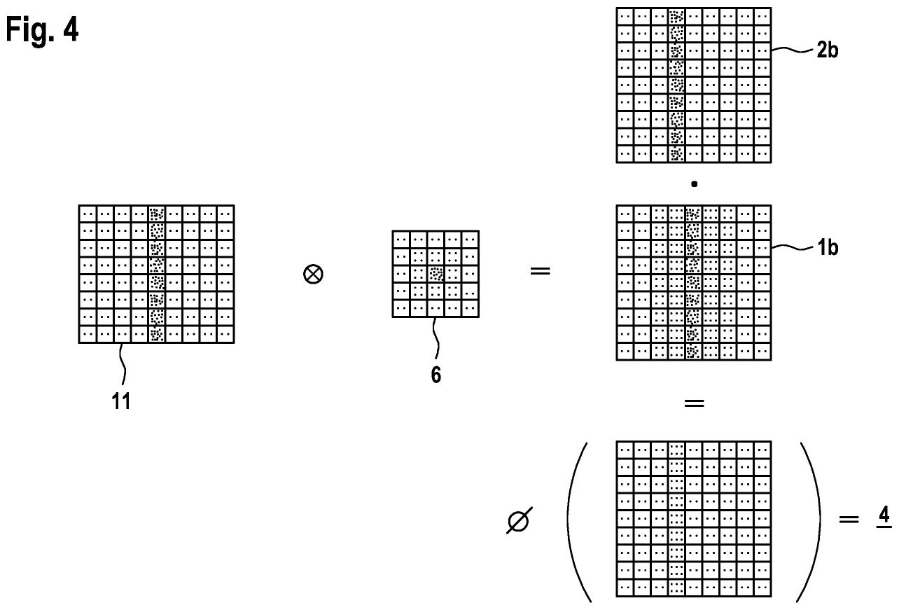

FIG. 4 schematically illustrates the way in which a fingerprint 1b may be ascertained with the aid of filtering using a filter core 6 and then be offset against a second fingerprint 2b to form a similarity 4. In the example shown in FIG. 1, the lane positions in the two driving situations that are characterized by representations 1 and 2 are slightly offset horizontally. In the matrices, the point densities in the individual elements indicate the values of these elements. The greater the point density in an element, the greater the value of this element.

First representation 1 relates to the driving situation in which the lane position is precisely centered. Matrix M, in which occupancies 53a are combined, thus has in the center a column which has especially high values. The filtering of this matrix M with the aid of filter core 6 causes the high values generated in resulting fingerprint 1b to be slightly “blurred” to the left and right.

Second representation 2 relates to the driving situation in which the lane position is slightly offset to the left. Fingerprint 2b, which is generated without filtering and in which occupancies 53a′ are combined, thus has especially high values in a column to the left of the center. If this fingerprint 2b is multiplied in an element-wise manner by fingerprint 1b, then an intermediate result is obtained in which a column is situated to the left of the center which now has only moderately high values. The formation of the average value or median across all elements of this intermediate result supplies the searched-for similarity 4. If the lane position in the second driving situation would also have been centered, then this similarity would have been considerably higher.

1-15. (canceled)

16. A method for comparing two digital representations of driving situations of a vehicle, the digital representations including occupancy information about an occupancy of the environment of the vehicle by traffic-relevant objects, the method comprising the following steps:
subdividing a region of the environment of the vehicle into a grid of subregions;
ascertaining, based on the occupancy information in the first digital representation, occupancies of the subregions by traffic-relevant objects, and combining them to form a first fingerprint of the first driving situation;
ascertaining, based on the occupancy information in the second digital representation, occupancies of the subregions by traffic-relevant objects, and combining them to form a second fingerprint of the second driving situation;
ascertaining a similarity measure between the first fingerprint and the second fingerprint according to a predefined measure specification; and
determining that the first and second driving situations are identical or at least similar based on the similarity measure satisfying a predefined criterion.

17. The method as recited in claim 16, wherein it is binarily detected respectively in one bit in each case whether a subregion is occupied by at least one traffic-relevant object.

18. The method as recited in claim 17, wherein the bits acquired for all subregions are combined in a binary number as a fingerprint.

19. The method as recited in claim 18, wherein a significance of a bit in the binary number is lower or higher the greater the importance of an object in the corresponding subregion for a behavior strategy of the vehicle in the first or second driving situation.

20. The method as recited in claim 18, wherein the similarity measure is a function of a length of a bit sequence that is identical in both the first and second fingerprints.

21. The method as recited in claim 17, wherein the similarity measure is a function of a Hamming distance between the first and second fingerprints.

22. The method as recited in claim 16, wherein the occupancies acquired for all subregions are combined in a matrix in each case and the first and second fingerprints are formed therefrom.

23. The method as recited in claim 22, wherein at least the matrix generated from one of the first or second digital representations is converted into the first or second fingerprint with the aid of filtering using at least one filter core.

24. The method as recited in claim 22, wherein the similarity measure includes an average value or median of elements in an elementwise product of both the first and second fingerprints.

25. The method as recited in claim 16, wherein the first digital representation is ascertained from at least one simulation of a driving situation and the second digital representation is ascertained from at least one recording of measured data recorded using at least one sensor during a drive of a vehicle.

26. A method for validating a simulation of a drive of a vehicle, the method comprising the following steps:
converting at least one simulated driving situation of a simulated drive into a first digital representation;
ascertaining second digital representations of a multitude of reference drives within the reference drives from time characteristics of reference drives;
comparing the first digital representation of the simulated driving situation against each of the second digital representations of the reference driving situations, the first and second digital representations including occupancy information about an occupancy of the environment of the vehicle by traffic-relevant objects, the comparing including, for each of the second digital representations:
subdividing a region of the environment of the vehicle into a grid of subregions,
ascertaining, based on the occupancy information in the first digital representation, occupancies of the subregions by traffic-relevant objects, and combining them to form a first fingerprint of the first driving situation,
ascertaining, based on the occupancy information in the second digital representation, occupancies of the subregions by traffic-relevant objects, and combining them to form a second fingerprint of the second driving situation,
ascertaining a similarity measure between the first fingerprint and the second fingerprint according to a predefined measure specification, and
determining that the first and second driving situations are identical or at least similar based on the similarity measure satisfying a predefined criterion;
ascertaining from results of the comparisons at least one reference driving situation within a reference drive that is identical or at least similar to the simulated driving situation;
comparing a characteristic of the simulated drive following the simulated drive situation with a characteristic of the reference drive following the ascertained reference driving situation; and
determining that the simulation of the drive is valid at least for the simulated driving situation when the following characteristic of the simulated drive is in line according to the predefined criterion with the following characteristic of the reference drive.

27. The method as recited in claim 26, wherein brake danger parameters and/or required steering potentials reached in the following characteristics of the simulated and the reference drive to mitigate the danger are used for the comparison of the following characteristics.

28. A non-transitory machine-readable data carrier on which is stored a computer program for comparing two digital representations of driving situations of a vehicle, the digital representations including occupancy information about an occupancy of the environment of the vehicle by traffic-relevant objects, the computer program, when executed by a computer, causing the computer to perform the following steps:
subdividing a region of the environment of the vehicle into a grid of subregions;
ascertaining, based on the occupancy information in the first digital representation, occupancies of the subregions by traffic-relevant objects, and combining them to form a first fingerprint of the first driving situation;
ascertaining, based on the occupancy information in the second digital representation, occupancies of the subregions by traffic-relevant objects, and combining them to form a second fingerprint of the second driving situation;
ascertaining a similarity measure between the first fingerprint and the second fingerprint according to a predefined measure specification; and
determining that the first and second driving situations are identical or at least similar based on the similarity measure satisfying a predefined criterion.

29. A computer configured to compare two digital representations of driving situations of a vehicle, the digital representations including occupancy information about an occupancy of the environment of the vehicle by traffic-relevant objects, the computer configured to:
subdivide a region of the environment of the vehicle into a grid of subregions;
ascertain, based on the occupancy information in the first digital representation, occupancies of the subregions by traffic-relevant objects, and combining them to form a first fingerprint of the first driving situation;
ascertain, based on the occupancy information in the second digital representation, occupancies of the subregions by traffic-relevant objects, and combining them to form a second fingerprint of the second driving situation;
ascertain a similarity measure between the first fingerprint and the second fingerprint according to a predefined measure specification; and
determine that the first and second driving situations are identical or at least similar based on the similarity measure satisfying a predefined criterion.
